(19) United States
(12) Patent Application Publication
(10) Pub. No.: US 2022/0216370 A1
(43) Pub. Date: Jul. 7, 2022

(54) LED FLIP CHIP, FABRICATION METHOD THEREOF AND DISPLAY PANEL

(71) Applicant: CHONGQING KONKA PHOTOELECTRIC TECHNOLOGY RESEARCH INSTITUTE CO., LTD., Chongqing (CN)

(72) Inventor: CHEN HUNG-WEN, Xinzhu (TW)

(73) Assignee: CHONGQING KONKA PHOTOELECTRIC TECHNOLOGY RESEARCH INSTITUTE CO., LTD., Chongqing (CN)

(21) Appl. No.: 17/703,996

(22) Filed: Mar. 25, 2022

Related U.S. Application Data
(63) Continuation of application No. PCT/CN2020/101728, filed on Jul. 13, 2020.

(51) Int. Cl. H01L 33/38; H01L 33/00; H01L 25/075; H01L 33/20

(52) U.S. Cl. CPC H01L 33/38; H01L 33/0093; H01L 25/0753; H01L 33/32; H01L 33/0075; H01L 33/007; H01L 33/20

(57) ABSTRACT

The present invention involves a LED flip chip, its fabrication method and a display panel containing the LED flip chip. The LED flip chip comprises a first semiconductor layer, a second semiconductor layer, an active layer configured between the first and second semiconductor layers, a first electrode and a second electrode. At least one of the first and second electrodes includes at least two sub-electrodes.

### CROSS REFERENCE TO RELATED APPLICATION

The present application is a continuation application of PCT/CN2020/101728 filed on Jul. 13, 2020. The disclosure of the forgoing application is hereby incorporated by reference in its entirety, including any appendices or attachments thereof, for all purposes.

### TECHNICAL FIELD

The present invention relates to light emitting display (LED) fields, specifically relates to a LED flip chip, its fabrication method and a display panel using it.

### BACKGROUND

Nowadays, micro-LEDs will be mass transferred to a driving back plane after being fabricated so as to make a display panel. Melting metal is usually applied on the driving back plane, and then electrodes of the micro-LEDs will be inserted into the melting metal. After the melting metal is solidified, the micro-LEDs can be fixed and electrically connected to the driving back plane. However, it would be difficult to ensure a reliable connection between the electrodes of the micro-LEDs and corresponding circuits on the driving back plane since a large quantity of micro-LEDs will be involved in a mass transfer process. Therefore, it would be occurred that some micro-LEDs may not be well connected to the circuits on the driving back plane after the mass transfer thereby resulting in unreliable electrical connections.

Hence, there is a problem of how to improve the reliability of the connections between the micro-LEDs and the driving back plane.

### SUMMARY

The present invention aims to provide a LED flip chip, its fabrication method and a display panel using it to address the above-mentioned problem. The present invention as disclosed in the disclosure can solve the problem that micro-LEDs can't be safely bound to the metal on the driving back plane thereby leading to invalid electrical connections therebetween.

A LED flip chip, comprising:

a first semiconductor layer;

a second semiconductor layer;

an active layer configured between the first semiconductor layer and the second semiconductor layer;

a first electrode configured on a side of the first semiconductor layer away from the active layer;

a second electrode configured on a side of the second semiconductor layer close to the active layer; and

at least one of the first electrode and the second electrode including n pieces of sub-electrodes, wherein n is an integer greater than 2.

As at least one of the two electrodes includes at least two sub-electrodes, the electrodes of said LED flip chip can be reliably connected to the driving back plane as long as at least one of the sub-electrodes forms a valid connection with the melting metal when the electrodes containing the at least two sub-electrodes are joined with the melting metal on the driving back plane. As such, it will greatly increase a success rate of binding the LED flip chip to the driving back plane, decrease a failure rate thereof, and thus improve fabrication efficiency and product quality of the display panel.

Optionally, the first semiconductor layer is a P-type semiconductor layer while the second semiconductor layer is an N-type semiconductor layer.

Optionally, the n pieces of sub-electrodes comprise rod-shaped electrodes.

As according cross-sectional areas of free ends of the rod-shaped sub-electrodes are relatively small in the LED flip chip, corresponding contact areas thereof are relatively small when the LED flip chip is inserted into the melting metal, which may enhance the intensity of pressure on contact areas between the electrodes and the melting metal when a same pressure is brought upon the LED flip chip. In other words, the pressure needed to insert the electrodes of the LED flip chip into the melting metal may be decreased which may reduce a risk that the LED flip chip may sink into a transient substrate, but couldn't be separated from it because the contact area between the LED flip chip and the transient substrate bears an excessive pressure thereupon.

Optionally, the n pieces of sub-electrodes may comprise cylindrical sub-electrodes. The cylindrical sub-electrodes are hollow and have openings at free ends thereof. The rod-shaped sub-electrodes are located within corresponding cylindrical sub-electrodes.

The present invention reduces not only the pressure needed to bind the LED flip chip to the driving back plane, but also the possibility of sinking the LED flip chip into the transient substrate due to a possible over-pressure. Furthermore, because of adopting the cylindrical sub-electrodes with the openings at their free ends, when inserting the LED flip chip into the melting metal of the driving back plane, the cylindrical sub-electrodes may help avoid a problem that the melting metal inside the cylindrical sub-electrodes may overflow due to the squeeze by the rod-shaped sub-electrodes, and thus improve the joining reliability between the rod-shaped sub-electrodes and the melting metal.

Optionally, free ends of the rod-shaped sub-electrodes are configured like thorns.

In the above embodiment, since the free ends of the rod-shaped sub-electrodes are like thorns, the pressure intensity at the contact area between the sub-electrodes and the melting metal may be further increased, while the pressure needed for binding the LED flip chip with the driving back substrate and the possibility of sinking the LED flip chip into the transient substrate may be decreased.

Optionally, the second semiconductor layer includes a hidden portion and an exposed portion at a side thereof toward the active layer. The hidden portion joins with the active layer. The exposed portion includes an epitaxial section and a second electrode configuring section for configuring the second electrode. The thickness of the epitaxial section is not equal to that of the second electrode configuring section. Any two points on a surface of the second semiconductor layer away from the active layer are located in a same plane.

In the LED flip chip, because an epitaxial layer is set on the second semiconductor layer, the area of the surface, away from the active layer, of the second semiconductor layer is expanded via the epitaxial section. That is to say, the area of a surface opposite to the surface of the LED flip chip, where the electrodes are located, is increased, thereby increasing the contact area between the LED flip chip and the transient substrate when the LED flip chip is bound to the driving back plane via the transient substrate. In this way, the pressure intensity on the contact area between the LED flip chip and the transient substrate may be decreased when a same pressure is brought to the LED flip chip by the transient substrate, which may reduce a risk that the LED flip chip sinks into the transient substrate due to an over-pressure so as to being inseparable from the transient substrate. In other words, a critical pressure bearable to the LED flip chip is increased in such a circumstance that the LED flip chip would not sink into the transient substrate.

Optionally, the thickness of the epitaxial section is less than that of the second electrode configuring section.

Optionally, the epitaxial section surrounds the hidden portion and the second electrode configuring section of the second semiconductor layer.

In the LED flip chip the epitaxial section is relatively thin, thus able to bear a pressure less than that other non-epitaxial sections can bear, and can't be lit up. Hence, the epitaxial section is configured to surround the non-epitaxial sections so that the epitaxial section may be allocated around the non-epitaxial sections evenly and thus not located in an area close to the center of the LED flip chip since it can't bear a big pressure. In this way, it may be avoided that possible clustering of areas which can't be lit up may adversely influence a display effect after the LED flip chip is lit.

Based on a same invention idea, the disclosure further provides a display panel, which comprises a driving back plane and a plurality of LED flip chips. First and second electrodes of each LED flip chip are both connected with corresponding circuits on the driving back plane electrically.

As at least one of the two electrodes includes at least two sub-electrodes, and a reliable connection between the electrodes as a whole and the driving back plane may be realized once at least one of the sub-electrodes forms a valid connection with melting metal of the driving back plane. It will greatly enhance a rate of success that the LED flip chip is bound to the driving back plane, decrease a failure rate of the display panel and thus increase a production efficiency and according product quality thereof.

Based on a same invention idea, the disclosure also provides a fabrication method of a LED flip chip, comprising:

forming an epitaxial layer of the LED flip chip, which includes a first semiconductor layer, a second semiconductor layer and an active layer between the first and second semiconductor layers;

etching the epitaxial layer from a side thereof where the first semiconductor layer is located, till the second semiconductor layer is exposed; and

configuring a first electrode on the first semiconductor layer and a second electrode on the second semiconductor layer, wherein the first electrode is configured on a side of the first semiconductor layer away from the active layer, the second electrode is configured on a side of the second semiconductor layer close to the active layer, and at least one of the first and second electrodes comprises n pieces of sub-electrodes, and wherein the n is an integer greater than 2.

In the fabrication process as above, at least one of the first and second electrodes is configured to include at least two sub-electrodes when preparing the electrodes of the LED flip chip, which enables that only at least one of the sub-electrodes is needed to form a valid connection with the melting metal in order to realize a reliable connection between the electrodes as a whole and the driving back plane. This could greatly enhance a rate that the LED flip chip is successfully bound to the driving back plane, decrease a failure rate of the display panel and increase a fabrication efficiency and product quality thereof.

Optionally, the n may be greater than 3, and the n pieces of the sub-electrodes may include cylindrical sub-electrodes and at least two rod-shaped sub-electrodes. The cylindrical sub-electrodes are hollow and have openings at free ends thereof, and the rod-shaped sub-electrodes are located within corresponding cylindrical sub-electrodes.

Optionally, free ends of the rod-shaped electrodes are configured like thorns.

Optionally, the step of etching the epitaxial layer from a side thereof, where the first semiconductor layer locates, till the second semiconductor layer is exposed includes:

etching the epitaxial layer from the side thereof, where the first semiconductor layer is located, till an epitaxial section of the second semiconductor layer is exposed; and

etching non-epitaxial sections of the second semiconductor layer from a side thereof where the first semiconductor layer is located, till a second electrode configuring section of the second semiconductor layer is exposed; wherein the thickness of the second electrode configuring section is different from that of the epitaxial section and any two points on a surface of the second semiconductor layer away from the active layer are located in a same plane.

In the fabrication process as above, because the epitaxial layer is configured on the second semiconductor layer, the area of a surface, away from the active layer, of the second semiconductor layer is expanded via the epitaxial section. That is, the area of a surface of the LED flip chip opposite to a surface, where the electrodes are located, is increased, which in fact increases a contact area between the LED flip chip and a transient substrate when the LED flip chip is bound to the driving back plane via the transient substrate. In this way, the pressure intensity on the contact area between the LED flip chip and the transient substrate may be decreased when a same pressure is brought to the LED flip chip by the transient substrate, which may reduce the risk that the LED flip chip sinks into the transient substrate due to an over-pressure so as to being inseparable from the transient substrate. In other words, a critical pressure bearable to the LED flip chip is increased in a circumstance that the LED flip chip would not sink into the transient substrate.

Optionally, after the epitaxial section of the second semiconductor layer is exposed and before etching the non-epitaxial sections of the second semiconductor layer from its side where the first semiconductor layer is located, it also comprises:

transferring the epitaxial layer from a growth substrate to the transient substrate, wherein an orientation of the epitaxial layer on the transient layer is same as its on the growth substrate.

The fabrication method may avoid a problem such as inconveniency in a transfer process caused by making the electrodes before the transfer process, and also difficulties of removing adhesives used and attached on the electrodes during the transfer process as the electrodes are made after the epitaxial layer is transferred to the transient substrate. It may thus increase the convenience of the transfer process and need no process of removing the adhesives from the electrodes.

Optionally, the step of transferring the epitaxial layer from the growth substrate to the transient substrate comprises:

adopting a temporary substrate with an adhesive layer to attach the first semiconductor layer of the epitaxial layer;

separating the second semiconductor layer from the growth substrate;

adopt a transient substrate with an adhesive layer to attach the second semiconductor layer of the epitaxial layer; and

separating the first semiconductor layer from the temporary substrate.

Optionally, the step of etching the epitaxial layer from the side thereof, where the first semiconductor layer is located, till the epitaxial section of the second semiconductor layer includes:

coating a photoresist layer onto the first semiconductor layer;

patterning the photoresist layer by using a halftone mask to form a plurality of photoresist sub-patterns, wherein gaps exist among the photoresist sub-patterns, each photoresist sub-pattern includes a first portion and a second portion, and the thickness of the second portion is greater than that of the first portion; and

starting to etch the photoresist layer from its side away from the first semiconductor layer, till the epitaxial layer at the gaps among the photoresist sub-patterns is completely etched off, wherein the epitaxial layer corresponding to the second portion is exposed out of the second semiconductor layer to form the epitaxial section, and the epitaxial layer corresponding to the first portion still remains the first semiconductor layer.

Optionally, the step of disposing the first electrode on the first semiconductor layer and the second electrode on the second semiconductor layer includes:

forming a metal electrode layer on the first and second semiconductor layers; and

patterning the metal electrode layer to obtain the first electrode and the second electrode, wherein n is greater than 3, n pieces of the sub-electrodes include cylindrical sub-electrodes and at least two rod-shaped electrodes, the cylindrical electrodes are hollow and have openings at free ends thereof, and the rod-shaped electrodes are located within corresponding cylindrical electrodes.

The fabrication method not only reduces the pressure needed to bind the LED flip chip to the driving back plane via configuring the rod-shaped sub-electrodes and thus the possibility of the LED flip chip sinking into the transient substrate due to the over-pressure for binding the chip by means of configuring the hollow cylindrical sub-electrodes with the openings at their free ends, but also avoids the problem that the melting metal inside the cylindrical sub-electrodes overflows due to the squeeze by the rod-shaped sub-electrodes when inserting the LED flip chip into the melting metal of the driving back plane. By doing this way, the reliability of joining the rod-shaped sub-electrodes and the melting metal.

Optionally, the step of disposing the first electrode on the first semiconductor layer and the second electrode on the second semiconductor layer includes:

adopting at least one of an evaporation process and a physical vapor deposition process to form the metal electrode layer on the first semiconductor layer and the second electrode configuring section.

### BRIEF DESCRIPTION OF THE DRAWINGS

FIG. 1 is an elevation view of a LED flip chip in a preferred embodiment in accordance with the present invention.

FIG. 2 is a sketch view showing the LED flip chip on a transient substrate in a preferred embodiment in accordance with the present invention.

FIG. 3 is an elevation view of another LED flip chip in a preferred embodiment in accordance with the present invention.

FIG. 4 is a top view of an electrode provided in another preferred embodiment in accordance with the present invention.

FIG. 5 is an elevation view of another LED flip chip in a preferred embodiment in accordance with the present invention.

FIG. 6 is a top view of a LED flip chip provided in a preferred embodiment in accordance with the present invention.

FIG. 7 is a top view of the LED flip chip in FIG. 5.

FIG. 8 is a flow chart of a fabrication method for a LED flip chip provided in another preferred embodiment in accordance with the present invention.

FIG. 9 is a flow chart of a first stage etching an epitaxial layer in another preferred embodiment in accordance with the present invention.

FIG. 10 is a sketch view showing a status change of the epitaxial layer during the first stage etching process in another preferred embodiment in accordance with the present invention.

FIG. 11 is a flow chart showing the epitaxial layer being transferred from a growth substrate to the transient substrate in another preferred embodiment in accordance with the present invention.

FIG. 12 is a sketch view showing the status change of the transfer process of FIG. 11.

### PART NUMBER DESCRIPTION

10—LED flip chip, 11—first semiconductor layer, 12—active layer, 13—second semiconductor layer, 14—first electrode, 15—second electrode, 20—transient substrate, 40—electrode, 41—cylindrical sub-electrode, 42—rod—shaped sub—electrode, 50—LED flip chip, 51—first semiconductor layer, 511—first electrode disposing section, 52—active layer, 53—second semiconductor layer, 54—first electrode, 55—second electrode, 530—hidden portion, 531—second electrode configuring section, 532—epitaxial section, 60—LED flip chip, 611—first electrode configuring section, 631—second electrode configuring section, 632—epitaxial section, 101—epitaxial layer, 1011—first semiconductor layer, 1012—second semiconductor layer, 1013—active layer, 102—phoresist layer, 121—transient substrate.

### DETAILED DESCRIPTION

In order to better understand the present invention, the present invention will be described in details below with reference to corresponding drawings. The drawings provide preferred embodiments in accordance with the present invention. However, the present invention may be realized via various ways, not limited to the embodiments described in the disclosure. On the contrary, the purpose of providing these embodiments is for facilitating a thorough and comprehensive understanding of the contents of the present invention.

Unless being otherwise defined, all technical and science terms used in the disclosure are in accordance with what the technical people in the technical field of the present invention may understand commonly. The terms in the disclosure are used to describe detailed embodiments, without an attempt of any limitation to the present invention.

In relevant conventional technologies, when a micro-LED chip is bound to a driving back plane, it may often happen that connections between the micro-LED chip and metal on the driving back plane are unreliable, which may lead to invalid electrical connections therebetween thereby adversely influencing the quality of an according display panel and fabrication efficiency thereof.

Based on this, the present invention is desired to provide a solution to these technical problems as mentioned above, and details will be described in following embodiments.

A Preferred Embodiment:

This embodiment provides a LED flip chip, whose structure is shown in FIG. 1.

The LED flip chip 10 comprises an epitaxial layer and electrodes. The epitaxial layer includes a first semiconductor layer 11, an active layer 12 and a second semiconductor layer 13. The active layer 12 is configured between the first semiconductor layer 11 and the second semiconductor layer 13. The electrodes include first electrodes 14 and second electrodes 15, among which the first electrodes are connected to the first semiconductor layer 11 while the second electrodes 15 are connected to the second semiconductor layer 13. As the LED flip chip 10 is a flipped or reversed structure, its light-emitting area and the electrodes are positioned on two opposite surfaces of the epitaxial layer. In this embodiment, the first electrodes 14 are configured to be on a side of the first semiconductor layer 11 away from the active layer 12 while the second electrodes 15 are configured on a side of the second semiconductor layer 13 close to the active layer 12. The light-emitting area of the LED flip chip 10 is on a side of the second semiconductor layer 13 away from the active layer 12.

In the preferred embodiment, the electrodes of the LED flip chip 10 include at least n pieces of sub-electrodes, wherein n is an integer greater than 2. That is, at least one of the first electrodes 14 and the second electrodes 15 of the LED flip chip 10 includes two sub-electrodes. For example, in FIG. 1, the first electrodes 14 of the LED flip chip 10 comprise two sub-electrodes, while the second electrodes 15 comprise three sub-electrodes. Technical people in the art shall understand that only one of the first electrodes 14 and the second electrodes 15 may include at least two sub-electrodes while the other one may include only one electrode in another embodiments although the first electrodes 14 and the second electrodes 15 both include at least two sub-electrodes in FIG. 1. The amounts of the sub-electrodes of the first electrodes 14 and the second electrodes 15 may be different in some other examples.

It may be appreciated that the sub-electrodes can greatly enhance a success rate of valid electrical connection between the electrodes and the driving back plane as the electrodes (the first or second electrodes) may comprise at least two sub-electrodes and at least one of the sub-electrodes can form a reliable electrical connection with the driving back plane thereby forming the reliable electrical connection between the whole electrodes and the driving back plane as a result. Under the circumstance of binding the LED flip chips 10 to the driving back plane via mass transfer, the possibility of a valid connection between the driving back plane and each LED flip chip 10 can be increased, thereby enhancing the yield rate, the quality and production efficiency of the display panels on the whole.

In some examples of the embodiment, n pieces of sub-electrodes of the electrodes comprise rod-shaped sub-electrodes. As its name suggests that a rod-shaped sub-electrode refers to a long and thin sub-electrode, like a rod. In FIG. 1, the sub-electrodes of the first electrodes 14 and the second electrodes 15 are all rod-shaped sub-electrodes. In another examples of the embodiment, only some of the sub-electrodes may be rod-shaped while the other sub-electrodes may be block shaped, curve line shaped, polygonal line shaped or even irregular shaped.

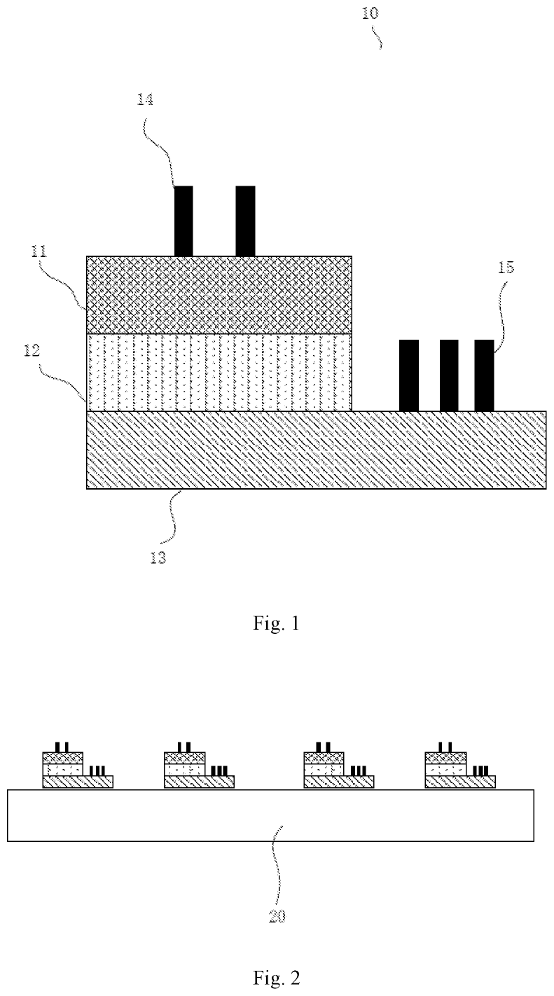

After a LED flip chip 10 is made, it will usually be mass transferred to the driving back plane. The last step of the mass transfer process is to transfer a plurality of LED flip chips 10 from the transient substrate to the driving back plane. As shown in FIG. 2, on the transient substrate 20, the plurality of LED flip chips 10 are configured with electrodes back facing the transient substrate 20. A force vertical to the transient substrate 20 is needed to be exerted onto the transient substrate 20 in order to transfer the LED flip chips 10 from the transient substrate 20 to the driving back plane, which will press the electrodes of the LED flip chips 10 into the melting metal of the driving back plane. The transient substrate 20 is then separated from the LED flip chips 10 and thus the transfer of the LED flip chips 10 from the transient substrate 20 to the driving back plane are completed. It can understood that the force should be increased as great as possible in order to enhance the reliability of the connections between the LED flip chips 10 and the driving back plane. However, an adhesive layer is set on the transient substrate 20 for attaching the LED flip chips 10, the LED flip chips 10 may sink into the adhesive layer of the transient substrate 20 if the force is excessively exerted, which may result in problems that the LED flip chips 10 couldn't be separated from the transient substrate 20 easily or even couldn't be normally separated.

In the embodiment, the sub-electrodes in the electrodes of the LED flip chip 10 include rod-shaped sub-electrodes which are thin and long and have relatively small cross sections of the free ends thereof, the free ends thereof are opposite to fixed ends thereof and the fixed ends thereof are fixed to the epitaxial layer. Compared to a possible solution only using a block-shaped electrode, rod-shaped sub-electrodes reduce a contact area between the electrodes of the LED flip chip 10 and the melting metal of the driving back plane when the electrodes are inserted into the driving back plane, which can increase the pressure intensity on the contact area between the electrodes and the melting metal in a circumstance that equal forces are exerted, enable the LED flip chip 10 to be inserted into the melting metal under a smaller pressure and thus avoid accidents of the LED flip chip 10 sinking into the transient substrate 20 due to an over-pressure being exerted onto the contact area between the LED flip chip 10 and the transient substrate 20.

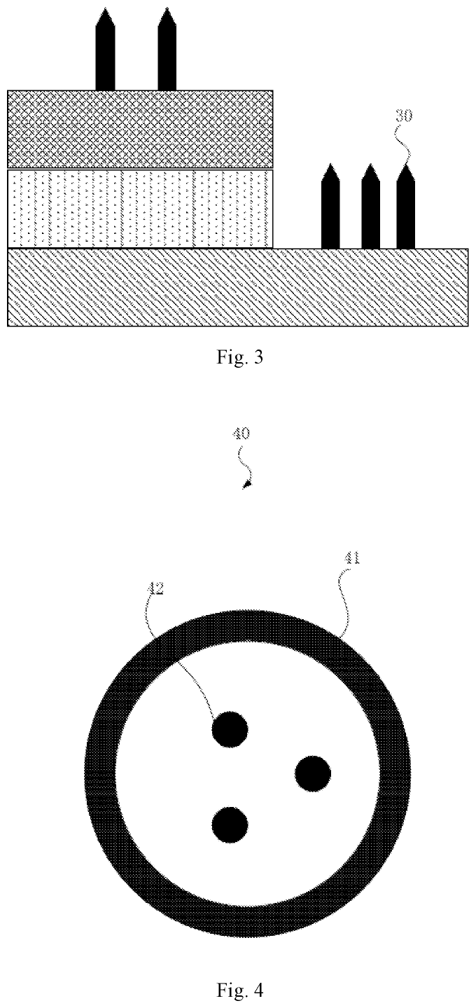

In order to further increase the pressure intensity on the contact area between the electrodes and the melting metal, in another examples of the embodiment, the free ends of the rod-shaped sub-electrodes may be made like thorns which may make the rod-shaped sub-electrodes looking like sharp arrows as a whole, as in FIG. 3. In this way, the rod-shaped sub-electrodes 30 can be more easily inserted into the melting metal of the driving back plane.

In some examples of the embodiment, besides the rod-shaped sub-electrodes, the n pieces of sub-electrodes of the electrodes may include cylindrical sub-electrodes. The cylindrical sub-electrodes look like hollow cylinders with openings at their free ends. When the electrodes include cylindrical sub-electrodes, the rod-shaped sub-electrodes are arranged in the cylindrical sub-electrodes, for example, FIG. 4 shows a top view of the electrodes comprising the rod-shaped sub-electrodes and a cylindrical sub-electrode at the same time. The electrode 40 includes a cylindrical sub-electrode 41 and three rod-shaped sub-electrodes 42 positioned inside the cylindrical sub-electrode 41. There is no doubt that although the cross section of the cylindrical sub-electrodes are circles, the cylindrical sub-electrodes 41 may have cross sections with other closed profiles such as regular figures like rectangular, triangle, pentagon or hexagon, or even irregular figures.

When the cylindrical sub-electrodes 41 are inserted into the melting metal, they may maintain some melting metal therein which will not overflow out of the cylindrical sub-electrodes 41 due to the squeeze by the rod-shaped sub-electrodes 42. This can help a better joining between the melting metal, the cylindrical sub-electrodes 41 as well as the rod-shaped sub-electrodes in the cylindrical sub-electrodes 42.

Furthermore, by configuring a plurality of sub-electrodes, it can increase a superficial area of the electrodes on the whole to certain degree and thus enable the LED flip chip to deliver greater currents in works.

To solve problems that the LED flip chip 10 may easily sink into the transient substrate when being bound to the driving back plane, on one hand the contact area between the LED flip chip 10 and the driving back plane can be reduced in the above described way, i.e., by reducing the contact area between the electrodes of the LED flip chip 10 and the driving back plane; and on the other hand, the contact area between the LED flip chip 10 and the transient substrate 20 may be considered to be increased. In the embodiment, the surface where the LED flip chip 10 contacts the transient substrate 20 is the side (surface) of the second semiconductor layer 13 away from the active layer 12. Therefore, increasing the area of the surface may increase a critical pressure the LED flip chip 10 can bear before it sinks into the transient substrate 20.

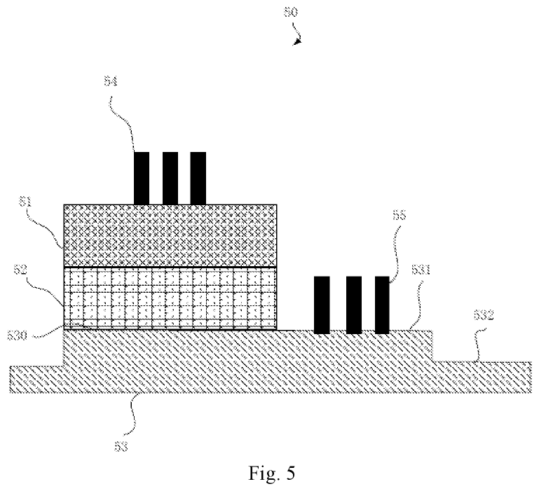

With reference to FIG. 5, the elevation view of another LED flip chip is shown.

The LED flip chip 50 comprises a first semiconductor layer 51, a second semiconductor layer 53 and an active layer 52 configured between the first semiconductor layer 51 and the second semiconductor layer 53. In the meantime, the LED flip chip 50 also includes first electrodes 54 and second electrodes 55. The first electrodes 54 are configured on a side of the first semiconductor layer 51 away from the active layer 52, while the second electrodes 55 are configured on a side of the second semiconductor layer 53 close to the active layer 52. The second semiconductor layer 53 includes a hidden portion 530 and an exposed portion on a side thereof toward the active layer 52. The hidden portion 530 joins with the active layer 52, and the exposed portion comprises a second electrode configuring section 531 for configuring the second electrodes 55. Fixed ends of the second electrodes 55 are fixed with the second electrode configuring section 531.

However, the exposed portion also includes an epitaxial section 532 beside the second electrode configuring section 531 in the embodiment. The epitaxial section 532 is functioned mainly to increase the area of the side of the second semiconductor layer 53 away from the active layer 52. FIG. 5 shows that the thickness of the epitaxial section 532 is different from that of the second electrode configuring section 531, specifically, smaller than the thickness of the second electrode configuring section 531. But, in another examples of the embodiment, the epitaxial section 532 and the second electrode configuring section 531 may have a same thickness. Or, the epitaxial section 532 may be thicker than the second electrode configuring section 531.

It shall be understood that the surface of the second semiconductor layer 53 away from the active layer 52 should be kept planar all the time no matter what the thickness relationship between the epitaxial section 532 and the second electrode configuring section 531 would be, in order to ensure the flatness of the light-emitting surface of the LED flip chip 50. That is to say, any two points on the surface of the second semiconductor layer 53 away from the active layer 52 shall lie in a same plane.

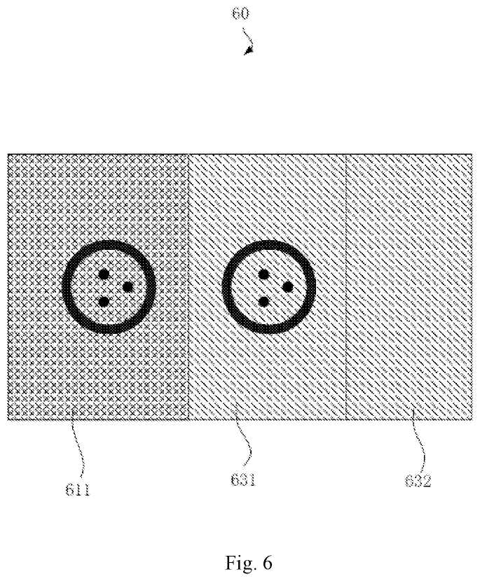

In some examples of the embodiment, the second electrode configuring section 531 and the hidden portion 530 are adjacent to each other closely, that is, they are not separated by the epitaxial section 532. In some examples of the embodiment, the epitaxial section 532 may be configured only at a side of a non-epitaxial section which consists of the hidden portion 530 and the second electrode configuring section 531. For example, with reference to FIG. 6 showing a top view of the LED flip chip 60, the LED flip chip 60 is divided into three districts in a row including a first electrode disposing section 611, a second electrode configuring section 631 and an epitaxial section 632. Of course, in some other examples, the epitaxial section 632 may be configured over or under the second electrode configuring section 631. Even in another examples with a looking-down view, the first electrode configuring section 611, the second electrode configuring section 631 and the epitaxial section 632 of the LED flip chip 60 may be arranged in an irregular way.

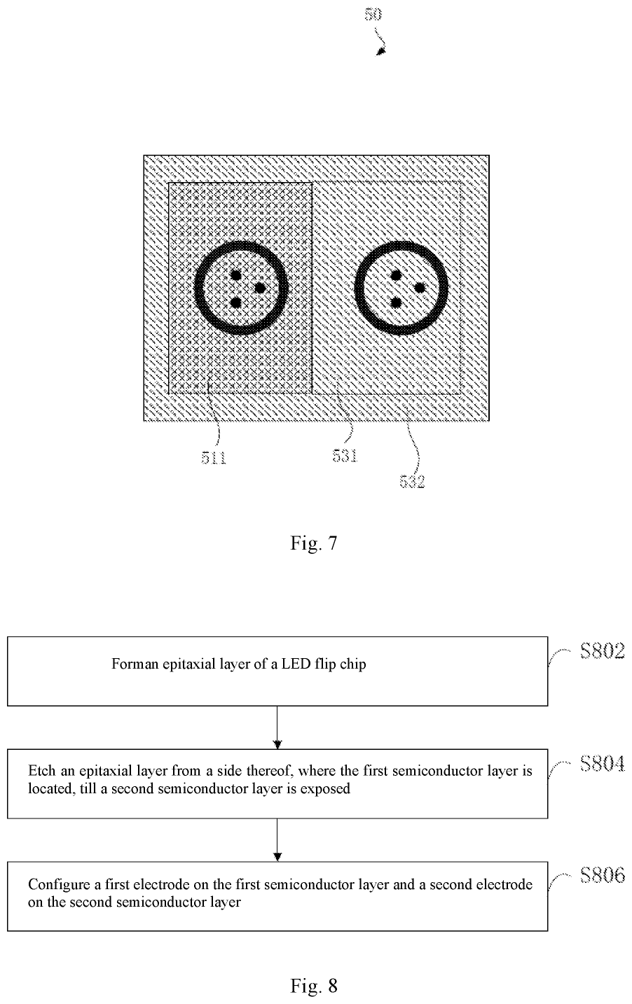

In some examples of the embodiment, the epitaxial section 532 may be configured also to surround the non-epitaxial section as shown in FIG. 7 which is a top view of the LED flip chip 50 of FIG. 5. In FIG. 7, the epitaxial section 532 surrounds the non-epitaxial section to form a closed ring. In the middle of the epitaxial section 532, the first electrode configuring section 511 is at the left while the second electrode configuring section 531 is at the right. It should be understood that as the epitaxial section 532 is thinner than the second electrode configuring section 531, the epitaxial section 532 can bear a relatively small pressure. The epitaxial section 532 may spread around the non-epitaxial section evenly by making the epitaxial section 532 to surround the non-epitaxial section. In other words, the epitaxial section 532 is distributed in the edge district of the LED flip chip 50 thereby avoiding being configured in a relatively centered district of the LED flip chip 50 since the epitaxial section 532 could not bear a relatively great pressure. Moreover, although a relative big area is remained at the side of the second semiconductor layer 53 away from the active layer 52, this does not increase the light-emitting area of the LED flip chip 50 and the light-emitting area of the LED flip chip 50 is still a district where the active layer 52 corresponds to. On the other hand, the epitaxial section 532, which can't emit lights, can be evenly distributed around the light-emitting area by configuring the epitaxial section 532 to surround the non-epitaxial section, thereby avoiding a problem that an over-clustering of districts, which can't be lit, may adversely influence a display effect after the LED flip chip is lit.

In some example of the embodiment, the epitaxial section 532 may be configured to be between the second electrode configuring section 531 and the hidden portion 530. For example, the epitaxial section 532 surrounds the second electrode configuring section 532 and at the same time the epitaxial section 532 also surrounds the hidden portion.

The embodiment also provides a display panel. The display panel comprises a driving back plane to have a plurality of LED flip chips mounted on the driving back plane. First and second electrodes of the LED flip chips are electrically connected with corresponding circuits on the driving back plane. In the embodiment, the plurality of LED flip chips may be any of the LED flip chips as described above.

For the LED flip chips and the display panel provided in the embodiment, on one hand, the electrodes of the LED flip chips may be configured to have two or more sub-electrodes so as to enhance the reliability of the electrical connection between the LED flip chips and the driving back plane and improve the quality of the display panel. On the other hand, the sub-electrodes may be configured to be rod shaped, and a contact area between the electrodes and the melting metal on the driving back plane can be reduced when binding the LED flip chips to the driving back plane, thereby enabling the LED flip chips being inserted into the melting metal under a smaller pressure, which may avoid that the LED flip chips sink into a transient substrate due to an over-pressure and thus facilitate a separation process between the LED flip chips and the transient substrate after the LED flip chips are bound.

Furthermore, by setting epitaxial sections in the LED flip chip, contact areas between their second semiconductor layers and the transient substrate are increased, a critical pressures that the LED flip chips could bear before sinking into the transient substrate is increased, while a risk that the LED flip chips sink into the transient substrate is decreased.

Another Optional Embodiment:

The embodiment provides a method of fabricating a LED flip chip with reference to the flow chart as shown in FIG. 8.

S802: forming an epitaxial layer of the LED flip chip.

The epitaxial layer includes a first semiconductor layer, a second semiconductor layer and an active layer between the first semiconductor layer and the second semiconductor layer. In some examples of the embodiment, the epitaxial layer can be grown on a growth substrate via an epitaxial growth process when forming the epitaxial layer. The growth substrate may be made of, but not limited to, a sapphire or gallium arsenide substrate.

S804: etching the epitaxial layer starting from a side thereof, where the first semiconductor layer is located, till the second semiconductor layer is exposed.

The epitaxial layer may be etched once it is grown. In the embodiment, a side of the second semiconductor layer away from the active layer will be a light-emitting side. Hence, electrodes of the LED flip chip will be configured at a side of the epitaxial layer opposite to the light-emitting side, and thus a side of the epitaxial layer where the first semiconductor layer is located will be firstly etched when etching the epitaxial layer. It shall be understood that a portion of the second semiconductor layer should be at least ensured to be exposed for forming a second electrode configuring section when the etching process is completed. Second electrodes may be configured on the second electrode configuring section.

In some examples of the embodiment, the etching process of the epitaxial layer may be divided into two phases:

Phase 1: etching the epitaxial layer starting from its side where the first semiconductor layer is located till an epitaxial section of the second semiconductor layer is exposed.

Phase 2: etching the non-epitaxial section of the second semiconductor layer starting from its side where the first semiconductor layer is located till the second electrode configuring section is exposed.

The etching process of the phase 1 will be introduced first below.

In relevant technologies, the epitaxial layer where the epitaxial section is configured will be completely etched off, but in the embodiment in accordance with the present invention, only the first semiconductor layer in this district, the active layer and probably part of the second semiconductor layer will be etched off. But not all of the second semiconductor layer in this district will be completely etched off, and a part thereof will be remained un-etched for forming the epitaxial section. The epitaxial section is configured mainly for increasing a contact area between the second semiconductor layer and the transient substrate.

In some examples, the thickness of the epitaxial section is different from that of the second electrode configuring section in the LED flip chip, e.g., less than the thickness of the second electrode configuring section. However, in some other examples of the embodiment, the thickness of the epitaxial section may be equal to, or greater than that of the second electrode configuring section.

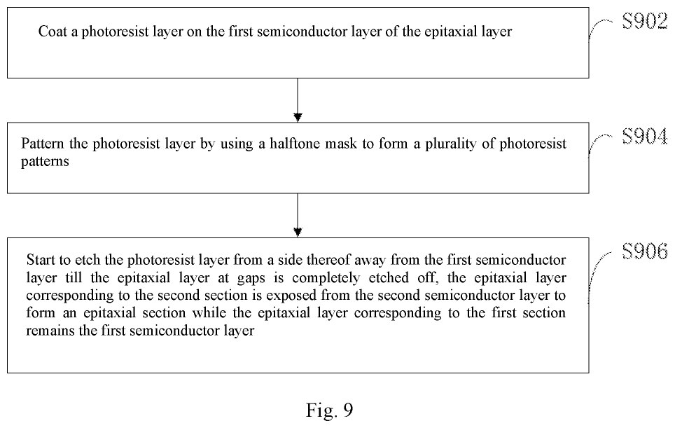

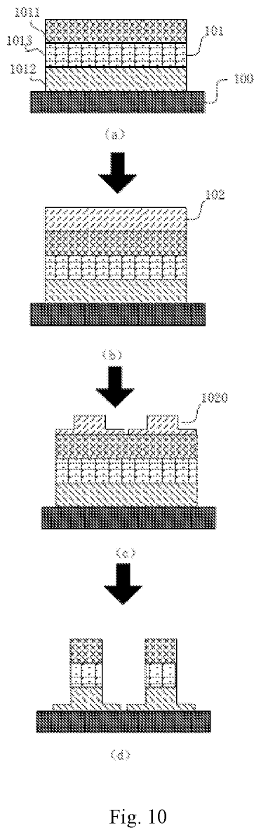

Below gives an illustration regarding the process of etching the epitaxial layer till the epitaxial section is exposed with reference to the flow chart of FIG. 9 and the status change drawing of etching the epitaxial layer of FIG. 10.

S902: coating a photoresist layer on the first semiconductor layer of the epitaxial layer.

With reference to status drawings (a) and (b) of FIG. 10, the status drawing (a) shows an epitaxial layer 101 on a growth substrate 100. The epitaxial layer 101 comprises a first semiconductor layer 1011, a second semiconductor layer 1012 and an active layer 1013. Among which, the active layer 1013 is between the first semiconductor layer 1011 and the second semiconductor layer 1012. In some examples of the embodiment, the first semiconductor layer 1011 is a P-type semiconductor layer, e.g., P—GaN, etc., while the second semiconductor layer 1012 is an N-type semiconductor layer such as N—GaN, etc. Of course, in some examples of the embodiment, the first semiconductor layer may also be an N-type semiconductor layer while the second semiconductor layer is a P-type semiconductor layer.

State drawing (b) shows a status that the photoresist layer 102 is formed after the photoresist layer is coated on the first semiconductor layer 1011.

S904: patterning the photoresist layer by use of a halftone mask to form a plurality of photoresist patterns.

In the embodiment, gaps exist among each photoresist patterns and this is to divide the epitaxial layer as a whole etching unit into a few independent sections. Each photoresist pattern 1020 is used to form an epitaxial layer of a corresponding LED flip chip. For example, the status drawing (c) shows two photoresist patterns 1020, then epitaxial layers of two LED flip chips may be obtained after patterning the epitaxial layer 101 according to the photoresist layer. In the embodiment, each photoresist pattern 1020 includes a first section and a second section, and the thickness of the second section is less than that of the first section in some examples.

S906: starting to etch a side of the photoresist layer away from the first semiconductor layer till the epitaxial layer at the gaps between the photoresist patterns is completely etched off, the epitaxial layer corresponding to the second section is exposed from the second semiconductor layer to form the epitaxial section, and the epitaxial layer corresponding to the first section remains to have the first semiconductor layer.

It can be understood that if some portions of the epitaxial layer are covered by the photoresist layer when etching, the photoresist layer will be etched firstly. After the photoresist layer is completely etched off, the first semiconductor layer 1011 of the epitaxial layer will be etched, then it is the active layer 1013 to be etched and the last is the second semiconductor layer 1012 to be etched. Similarly, if some portions, such as the gaps between the photoresist patterns, of the epitaxial layer are not covered by the photoresist layer when etching, such portions will be directly etched from the beginning. Obviously, different sections of the epitaxial layer 101 may be etched by different degrees according to whether there is a photoresist layer or not and the thickness differences of photoresist layers. The etching process after configuring the patterned photoresist layer may also be understood to be a process of “rubbing” patterns of the photoresist layer onto the epitaxial layer.

In the embodiment, when the etching process is completed, it is required that the epitaxial layer at the gaps between the photoresist patterns will be completely etched off, the epitaxial layer corresponding to the second section will be exposed out of the second semiconductor layer to form the epitaxial section, and the epitaxial layer corresponding to the first section will remain to have the first semiconductor layer, with reference to status drawing (d) of FIG. 10. Therefore, when configuring the patterned photoresist layer, the thickness of all sections of the photoresist layer should be considered. For example, the thickest section of the photoresist layer should at least ensure that the first semiconductor layer corresponding to the thickest portion is exposed, but has not been etched basically, and even has not been etched at all when “the epitaxial layer at the gaps between the photoresist patterns is completely etched off and the epitaxial layer corresponding to the second section is exposed out of the second semiconductor layer to form the epitaxial section”.

The etching process of the above-mentioned phase 2 will be illustrated below.

In some examples of the embodiment, the etching of the phase 2 will be started directly after etching the epitaxial layer of the phase 1 without any transfer. At this time, the epitaxial layer is still on the growth substrate. After the completion of the etching of the phase 2, electrodes are formed to finish the fabrication of the LED flip chip. Subsequently, the LED flip chip is transferred, e.g., the LED flip chip is firstly transferred onto a first transient substrate, and then transferred to a second transient substrate from the first transient substrate. Spacing between each LED flip chip on the second transient substrate should meet a requirement for being bound onto the driving back plane.

However, in some other examples of the embodiment, non-epitaxial sections of the epitaxial layer may be etched according to phase 2 after transferring the epitaxial layer, for example after the spacing between each LED flip chip on the second transient substrate meets the requirement for being bound to the driving back plane via the transfer process. In the latter circumstance, the epitaxial layer will not on the growth substrate during the etching process of the phase 2, and instead will be on the transient substrate. But, it should be understood that an orientation of the epitaxial layer on the transient substrate shall be the same with that on the growth substrate even if the epitaxial layer is transferred to the transient substrate because the etching orientations during the phase 1 and the phase 2 are the same, i.e., both are to start the etching from the side where the first semiconductor layer is located.

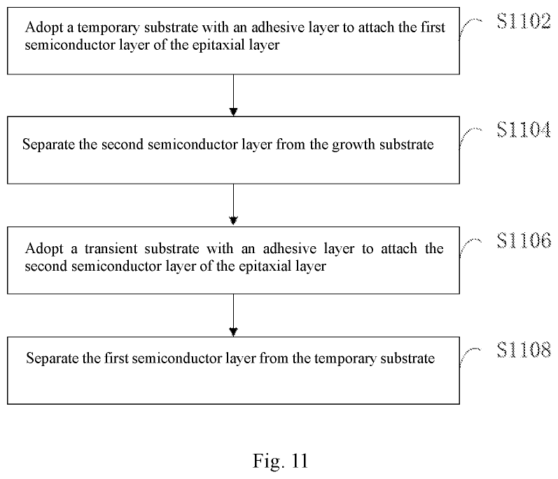

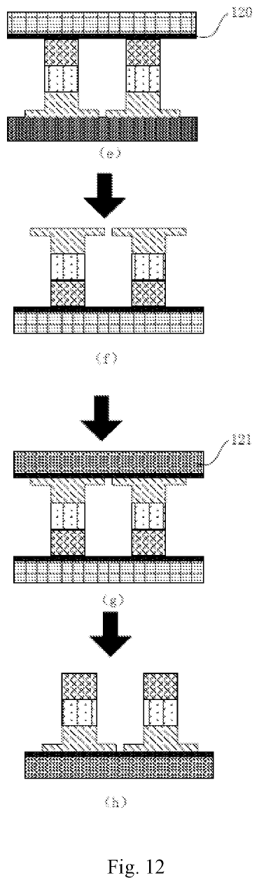

The process of transferring the epitaxial layer to the transient substrate will be illustrated with reference to the transfer flow chart of FIG. 11 and the transfer status change of FIG. 12.

S1102: adopting a temporary substrate with an adhesive layer to attach the first semiconductor layer of the epitaxial layer.

There is no substantial difference between the temporary substrate and the transient substrate, and different names are used to refer to the two substrates only for convenience purposes. They may be named as “first temporary substrate” and “second temporary substrate”, or as “first transient substrate” and “second transient substrate”.

Please refer to the status drawing (e) of FIG. 12, the temporary substrate 120 with the adhesive layer approaches the epitaxial layer from the side of the epitaxial layer where the first semiconductor layer is configured, and the adhesive layer is toward the epitaxial layer. In this way, the adhesive layer may be attached to the first semiconductor layer of each epitaxial layer.

S1104: separating the second semiconductor layer from the growth substrate.

Referring to the status drawing (f) of FIG. 12, the second semiconductor layer of each epitaxial layer may be peeled away from the growth substrate via ways such as LLO (Laser Lift-off), whereby the epitaxial layer is attached only onto the temporary substrate.

S1106: adopting a transient substrate with an adhesive layer to attach the second semiconductor layer of the epitaxial layer.

With reference to the status drawing (g) of FIG. 12, the transient substrate 121 with the adhesive layer approaches the epitaxial layer from its side where the second semiconductor layer is located, and the adhesive layer is toward the epitaxial layer. In this way, the adhesive layer of the transient substrate can be attached to the second semiconductor layer of each epitaxial layer. However, it is needed to note that the process of transferring the epitaxial layer from the temporary substrate to the transient substrate is a selected transfer process which can ensure that each epitaxial layer on the transient substrate may form the spacing between the LED flip chips meeting the requirement by the driving back plane.

S1108: separating the first semiconductor layer from the temporary substrate.

Also referring to the status drawing (h) of FIG. 12, the first semiconductor layer of each epitaxial layer can be peeled off from the temporary substrate by heating or illumination, such that the epitaxial layer is attached only onto the transient substrate.

After the transfer, the etching process of the phase 2 may be carried out regarding the epitaxial layer on the transient substrate, which is mainly regarding the non-epitaxial section of the epitaxial layer and will expose the second electrode configuring section by etching the non-epitaxial section.

S806: configuring/disposing first electrodes on the first semiconductor layer and second electrodes on the second semiconductor layer.

After etching the epitaxial layer till the second semiconductor layer is exposed to form the second electrode configuring section, electrodes may be configured on the first semiconductor layer and the second semiconductor layer. A first electrode may be directly configured on a remained section of the first semiconductor layer after the etching process while a second electrode may be configured on the second electrode configuring section exposed due to the etching process.

In the embodiment, the electrodes of the LED flip chips at least includes n pieces of sub-electrodes, and n is an integer greater than 2. That is, at least one of the first electrode and the second electrode include at least two sub-electrodes in one LED flip chip. In some examples of the embodiment, n may be an integer such as 2, 3, 4 . . . For example, in FIG. 1, the first electrode of the LED flip chip 10 includes two sub-electrodes and the second electrode 15 includes three sub-electrodes. However, in some other examples of the embodiment, only one of the first electrode 14 and the second electrode 15 may include at least two sub-electrodes, and the other one may only have one sub-electrode. Or, in another examples of the embodiment, the amount of the sub-electrodes of the first electrode 14 and the second electrode 15 may be set to be else.

Optionally, when forming the electrodes, a metal electrode layer may be formed on the first semiconductor layer and the second electrode configuring section, and then be patterned to form the first electrode and the second electrode. For example, the metal electrode layer may be made by evaporation (EV) process or physical vapor deposition (PVD) process. The first electrode and the second electrode may be or may not be made of the same metal. Hence, the metal electrode layer on the first semiconductor layer may be or may not be made of a same material as that of the metal electrode layer covering the second electrode configuring section. The material for making the metal electrode layer may include, but not limited to, Cr, Al, Ti, Ni, Au, etc. After the metal electrode layer is formed, it is to coat photoresist on the metal electrode layer to form the photoresist layer. It is then to obtain the patterned photoresist layer by photoetching, and after that the patterns on the photoresist layer will be printed onto the metal electrode layer by etching to form corresponding patterns on the metal electrode layer.

It may be understood that, because an electrode (the first electrode or the second electrode) may include at least two sub-electrodes and at least one of the sub-electrodes can form a reliable electrical connection with the driving back plane, which means that the whole electrodes have a reliable electrical connection with the driving back plane, such sub-electrodes can greatly enhance a success rate of establishing a valid connection between the electrodes and the driving back plane when the LED flip chip is bound to the driving back plane. In the circumstance that a possibility of effectively joining each Led flip chip with the driving back plane can be increased, the yield rate of the fabrication of the display panel will be increased, the quality of the display panel will be improved and the production efficiency will be accordingly increased on the whole.

In some examples of the embodiment, the n pieces of the sub-electrodes of the electrodes at least include rod-shaped sub-electrodes. The rod-shaped sub-electrodes refer to sub-electrodes which are thin and long, and look like rods. Please continue to refer to the LED flip chip in FIG. 1, the sub-electrodes of the first electrode 14 and the second electrode 15 are all rod-shaped sub-electrodes. In some other examples of the embodiment, an electrode may include some rod-shaped sub-electrodes and some other sub-electrodes which may be block-shaped, curve line-shaped, polygonal line shaped, or even some irregular shapes.

The sub-electrodes of the electrodes of the LED flip chip comprise rod-shaped sub-electrodes, and such rod-shaped sub-electrodes are thin, long and have relatively small cross sections at their free ends. Compared with a solution of only configuring one block-shaped electrode, this may reduce the contact area between the electrodes of the LED flip chip and the melting metal on the driving back plane when inserting the electrodes into the melting metal, increase the pressure intensity upon the contact area between the electrodes and the melting metal under a same force, enable the LED flip chip to be inserted into the melting metal under a smaller pressure and thus avoid such a circumstance from happening that the LED flip chip sinks into the transient substrate due to an over-pressure exerted upon the contact area between the LED flip chip and the transient substrate.

In order to further enhance the pressure intensity on the contact area between the electrodes and the melting metal, in some other examples of the embodiment, the free ends of the rod-shaped sub-electrodes may be configured to be like thorns and thus the rod-shaped sub-electrodes look like sharp arrows on the whole as shown in FIG. 3. As such, the rod-shaped sub-electrodes can be easily inserted into the melting metal.

In some examples of the embodiment, the n pieces of sub-electrodes may comprise cylindrical sub-electrodes beside the rod-shaped sub-electrodes. The cylindrical sub-electrodes are hollow cylinders with openings at free ends thereof. When the electrodes comprise cylindrical sub-electrodes, the rod-shaped sub-electrodes are located within corresponding cylindrical sub-electrodes. FIG. 4 shows a top view of one electrode including a cylindrical sub-electrode with rod-shaped sub-electrodes therein. The electrode 40 comprises a cylindrical sub-electrode 41 and three rod-shaped sub-electrodes 42 located within the cylindrical sub-electrode 41. There is no doubt that although the cross section of the cylindrical sub-electrode of FIG. 4 is a circle, it may be other closed regular profile such as rectangular, triangular, pentagon, hexagon and etc., or even irregular profile in another examples.

When the cylindrical sub-electrode 41 is inserted into the melting metal, it may maintain some melting metal within its interior and ensure the maintained melting metal not to overflow out of the cylindrical sub-electrode 41 because of a squeeze by the rod-shaped sub-electrodes 42. In this way, the melting metal, the cylindrical sub-electrode 41 and the rod-shaped sub-electrodes 42 inside the cylindrical sub-electrode 41 can be better joined.

The LED flip chip in the embodiment may include, but not limited to, Micro-LED, mini-LED, or OLED (Organic Light-Emitting Diode), etc.

In the fabrication method of the LED flip chip provided in the embodiment, when preparing the electrodes of the LED flip chip, at least one of the first electrode and the second electrode may be configured to be electrodes comprising at least two sub-electrodes, which can realize a reliable connection between the electrodes as a whole and the driving back plane as long as at least one of the sub-electrodes can form a valid connection with the melting metal when binding the LED flip chip to the driving back plane in the subsequent process. By doing so, it can greatly increase the success rate of binding the LED flip chip to the driving back plane, decrease the defect rate of the display panel and improve the production efficiency and product quality of the display panel.

Furthermore, since the epitaxial section is configured on the second semiconductor layer, the contact area between the LED flip chip and the transient substrate may be increased through the epitaxial section. When exerting a same forcepressure onto the LED flip chip via the transient substrate, the pressure intensity on the contact area therebetween may be decreased and also the risk, that the LED flip chip sinks into the transient substrate and thus the LED flip chip may become inseparable from the transient substrate due to the over-pressure, may be reduced.

In addition, by configuring the sub-electrodes to be rod-shaped, the contact area between the LED flip chip and the driving back plane may be decreased when binding the LED flip chip to the driving back plane, whereby the LED flip chip may be inserted into the melting metal under a smaller pressure and thus facilitate a separation process of the bound LED flip chip and the transient substrate.

It should be understood that applications of the present invention shall not be limited to the embodiments illustrated above. Ordinary technical people skilled in the art may be improved or altered in accordance with the above illustration. All such improvements and alterations should belong to the protection scope as defined in the claims of the present invention.

What is claimed is:

1. A LED flip chip, comprising:
a first semiconductor layer;
a second semiconductor layer; and
an active layer configured between the first semiconductor layer and the second semiconductor layer;
a first electrode configured on a side of the first semiconductor layer away from the active layer;
a second electrode configured on a side of the second semiconductor layer close to the active layer; wherein
at least one of the first electrode and the second electrode including n pieces of sub-electrodes, and the n is an integer greater than 2.

2. The LED flip chip according to claim 1, wherein the first semiconductor layer is a P-type semiconductor layer, and the second semiconductor layer is a N-type semiconductor layer.

3. The LED flip chip according to claim 1, wherein the n pieces of sub-electrodes comprise rod-shaped sub-electrodes.

4. The LED flip chip according to claim 3, wherein the n pieces of sub-electrodes also include cylindrical sub-electrodes, which are hollow and have openings at free ends thereof, and the rod-shaped sub-electrodes are located in corresponding cylindrical sub-electrodes.

5. The LED flip chip according to claim 3, wherein free ends of the rod-shaped sub-electrodes are like thorns.

6. The LED flip chip according to claim 4, wherein the second semiconductor layer comprises a hidden portion and an exposed portion on a side thereof toward the active layer, the hidden portion joins with the active layer, the exposed portion includes an epitaxial section and a second electrode configuring section for configuring the second electrode; and wherein the thickness of the epitaxial section is different from that of the second electrode configuring section, and any two points on a surface of the second semiconductor layer away from the active layer lie in a same plane.

7. The LED flip chip according to claim 6, wherein the epitaxial section is thinner than the second electrode configuring section.

8. The LED flip chip according to claim 6, wherein the epitaxial section surrounds the hidden portion of the second semiconductor layer and the second electrode configuring section.

9. A display panel, comprising a driving back plane and a plurality of the LED flip chips of claim 1, wherein the first electrode and the second electrode of each LED flip chip are both electrically connected with corresponding circuits on the driving back plane.

10. A fabrication method of a LED flip chip, comprising:
forming an epitaxial layer of the LED flip chip, which includes a first semiconductor layer, a second semiconductor layer and an active layer between the first and second semiconductor layers;
etching the epitaxial layer from a side thereof where the first semiconductor layer is located, till the second semiconductor layer is exposed;
configuring a first electrode on the first semiconductor layer and a second electrode on the second semiconductor layer; wherein the first electrode is configured on a side of the first semiconductor layer away from the active layer, the second electrode is configured on a side of the second semiconductor layer close to the active layer, and at least one of the first and second electrodes comprises n pieces of sub-electrodes, and wherein the n is an integer greater than 2.

11. The fabrication method of a LED flip chip according to claim 10, wherein the n is greater than 3, and the n pieces of the sub-electrodes include cylindrical sub-electrodes and at least two rod-shaped sub-electrodes; and wherein the cylindrical sub-electrodes are hollow and have openings at free ends thereof, and the rod-shaped sub-electrodes are located within corresponding cylindrical sub-electrodes.

12. The fabrication method of a LED flip chip according to claim 11, wherein free ends of the rod-shaped electrodes are configured like thorns.

13. The fabrication method of a LED flip chip according to claims 11, wherein the step of etching the epitaxial layer from a side thereof, where the first semiconductor layer is located, till the second semiconductor layer is exposed includes:
etching the epitaxial layer from the side thereof, where the first semiconductor layer is located, till an epitaxial section of the second semiconductor layer is exposed;
etching non-epitaxial sections of the second semiconductor layer from a side thereof where the first semiconductor layer is located, till a second electrode configuring section of the second semiconductor layer is exposed; wherein the thickness of the second electrode configuring section is different from that of the epitaxial section and any two points on a surface of the second semiconductor layer away from the active layer are located in a same plane.

14. The fabrication method of a LED flip chip according to claim 13, wherein after the epitaxial section of the second semiconductor layer is exposed and before etching the non-epitaxial sections of the second semiconductor layer from its side where the first semiconductor layer is located, it also comprises:
transferring the epitaxial layer from a growth substrate to the transient substrate, an orientation of the epitaxial layer on the transient layer is same with its on the growth substrate.

15. The fabrication method of a LED flip chip according to claim 14, wherein the step of transferring the epitaxial layer from the growth substrate to the transient substrate comprises:
adopting a temporary substrate with an adhesive layer to attach the first semiconductor layer of the epitaxial layer;
separating the second semiconductor layer from the growth substrate;
adopt a transient substrate with an adhesive layer to attach the second semiconductor layer of the epitaxial layer; and
separating the first semiconductor layer from the temporary substrate.

16. The fabrication method of a LED flip chip according to claim 13, wherein the step of etching the epitaxial layer from the side thereof, where the first semiconductor layer is located, till the epitaxial section of the second semiconductor layer includes:
coating a photoresist layer onto the first semiconductor layer;
patterning the photoresist layer by using a halftone mask to form a plurality of photoresist sub-patterns, wherein gaps exist among the photoresist sub-patterns, each photoresist sub-pattern includes a first portion and a second portion, and the thickness of the second portion is greater than that of the first portion;
starting to etch the photoresist layer from its side away from the first semiconductor layer, till the epitaxial layer at the gaps among the photoresist sub-patterns is completely etched off, wherein the epitaxial layer corresponding to the second portion is exposed out of the second semiconductor layer to form the epitaxial section, and the epitaxial layer corresponding to the first portion still remains the first semiconductor layer.

17. The fabrication method of a LED flip chip according to claim 13, wherein the step of disposing the first electrode on the first semiconductor layer and the second electrode on the second semiconductor layer includes:
forming a metal electrode layer on the first semiconductor layer and the second electrode configuring section;
patterning the metal electrode layer to obtain the first electrode and the second electrode.

18. The fabrication method of a LED flip chip according to claim 17, wherein the step of forming the metal electrode layer on the first semiconductor layer and the second electrode configuring section includes:
adopting at least one of an evaporation process and a physical vapor deposition process to form the metal electrode layer on the first semiconductor layer and the second electrode configuring section.
